(19) United States
(12) Patent Application Publication
(10) Pub. No.: US 2002/0182826 A1
(43) Pub. Date: Dec. 5, 2002

(54) Fabrication method for a shallow trench isolation structure

(76) Inventors: Shui-Ming Cheng, Hsinchu Hsien (TW); Yu-Shyang Huang, Taipei Hsien (TW); Yao-Chin Cheng, Hsinchu (TW); Kuei-Chi Juan, Hsinchu (TW); Chih-Chien Liu, Taipei (TW)

Correspondence Address: CHARLES C.H. WU & ASSOCIATES, Suite 710, 7700 IRVINE CENTER DRIVE, Irvine, CA, 92618-3043, US

(21) Appl. No.: 09/867,897

(22) Filed: May 29, 2001

(51) Int. Cl. H01L 21/76

(52) U.S. Cl. 438/433; 438/435

(57) ABSTRACT

A fabrication method for shallow trench isolation is provided. The method includes forming a pad oxide layer on a substrate, followed by forming a mask layer on the pad oxide layer. The mask layer is then patterned. Using the patterned mask as a mask, the pad oxide layer and the substrate are etched to form a trench in the substrate. A tilt-angled fluorine implantation is performed to form a substrate surface with fluorine ions around the top corner of the trench. A thermal oxidation process is further conducted on a surface of the trench to form a thicker liner oxide layer at the top corner of the trench. An insulation layer is then formed on the substrate, filling the trench. The insulation layer above the mask layer is removed followed by removing the mask layer and the pad oxide layer.

### BACKGROUND OF THE INVENTION

1. Field of Invention

This invention relates to a fabrication method for a device isolation structure. More particularly, the present invention relates to a shallow trench isolation structure.

2. Description of Related Art

The current integrated-circuit industry focuses on technological breakthroughs in device miniaturization and integration. As the device dimension gradually decreases, integration increases. The isolation structure of the device thus also decreases. The technical difficulty in forming the device isolation structure thereby increases. The device isolation structure prevents carriers from passing between the neighboring devices through the substrate. The device isolation structure formed in the dense semiconductor circuits, such as that formed between the field transistors of the dynamic random access memory, reduces the charge leakage generated by the field transistors. Conventionally, devices are isolated by forming a field oxide layer by means of local oxidation (LOCOS). Because of the formation of the bird's beak structure, the field oxide layer is limited from further reducing its dimension. As a result, other device isolation structures are developed, wherein the shallow trench isolation (STI) is the most widely applied, especially in the fabrication of the sub-half micron integrated circuit.

FIG. 1 is a schematic, cross-sectional view of a conventional shallow trench isolation structure.

As shown FIG. 1, a shallow trench isolation structure 116 is formed in a substrate 100. A liner layer 112 is further formed along the surface of the shallow trench isolation structure 116.

The fabrication of a conventional shallow trench isolation structure, a recess, however, is formed at the corner of the shallow trench isolation structure due to the attack of the etchant used in removing the pad oxide layer. The recess formed at the corner of the shallow trench isolation structure exposes a part of the substrate, leading to a current leakage during the operation of the device. Furthermore, the removal of the oxide layer in the subsequent semiconductor device manufacturing process employs wet dip etching, especially with the non-volatile products, which are formed with many layers of the oxide layer. For example, a flash memory comprises a tunnel oxide layer, the dielectric layer of the capacitor and the gate oxide layer in the peripheral circuit. As a result, the times of application of wet dip etching increases. A recess is thus formed in the shallow trench isolation structure because of the excessive times of etching performed on the different oxide layers. The corner of the shallow trench is more prone to being etched, exposing a part of the substrate as shown in FIG. 2.

FIG. 2 is a schematic, cross-sectional view of a conventional shallow trench isolation structure, wherein a corner of the shallow trench is etched and a portion of the substrate is exposed

As shown in FIG. 2, a recess is formed at the surface corner 214 of the shallow trench isolation structure 216, exposing a portion of the liner layer 212 and substrate 200 at the corner 214 of the trench 216. The excess is resulted from the etching of the oxide layers in the subsequent manufacturing process, which would lead to a current leakage during the operation of the device.

### SUMMARY OF THE INVENTION

The invention provides a fabrication method for a shallow trench isolation structure. This method comprises a formation of a pad oxide layer on a substrate, followed by forming a mask layer on the pad oxide layer. The mask layer is then patterned. Using the patterned mask layer as a mask, the pad oxide layer and the substrate are etched to form a trench in the substrate. A tilt-angled fluorine implantation is conducted to implant fluorine to the substrate surface around the top corner of the trench. A thermal oxidation process is further conducted to form a liner layer on the surface of the trench. A thicker liner layer is formed around the top corner of the trench. An insulation layer is then formed on the substrate filling the trench. The insulation layer above the mask layer is removed, followed by removing the mask layer and the pad oxide layer.

The present invention employs a tilt-angled fluorine implantation to provide the substrate surface around the trench corner with fluorine. When the thermal process is conducted to form the liner layer on the surface of the trench, the trench surface with the fluroine ions oxidizes at a faster rate, a thicker liner layer is thus formed around the corner of the trench than at other area. The corner of the trench is thus protected and is prevented from being exposed. As a result, during the removal of the oxide layer and the subsequent etching of the oxide layer as in the conventional practice, the formation of a recess at the top corner of the trench isolation structure is prevented to mitigate the current leakage problem of the device.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic, cross-sectional view of a conventional shallow trench isolation structure.

FIG. 2 is a schematic, cross-sectional view of a conventional shallow trench isolation structure, wherein a corner of the shallow trench is etched and a portion of the substrate is exposed.

FIGS. 3A through 3G are schematic, cross-sectional views, illustrating the successive fabrication steps of a shallow trench isolation structure according to one preferred embodiment of this invention.

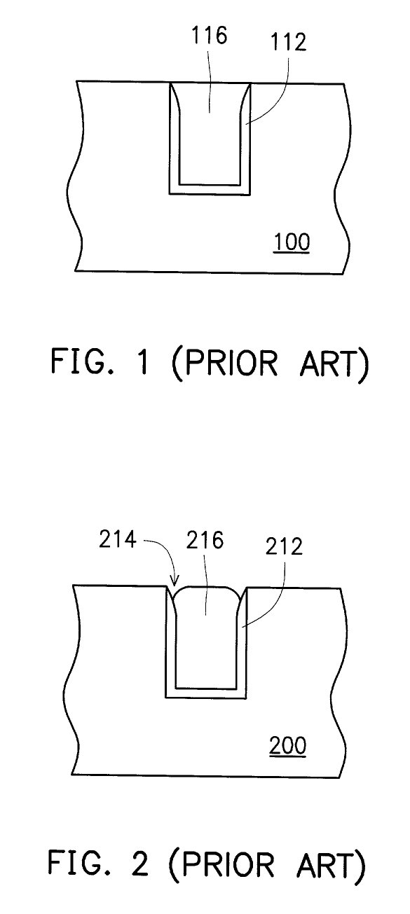

### DESCRIPTION OF THE PREFERRED EMBODIMENTS

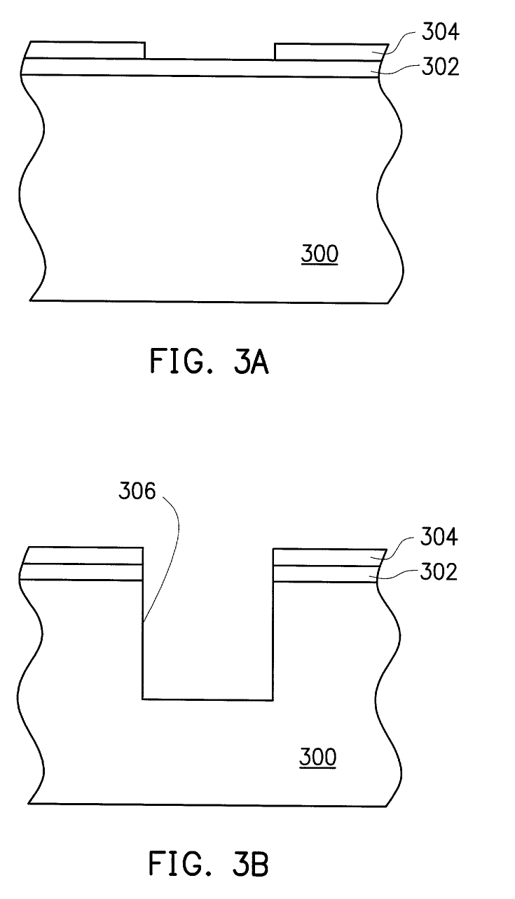

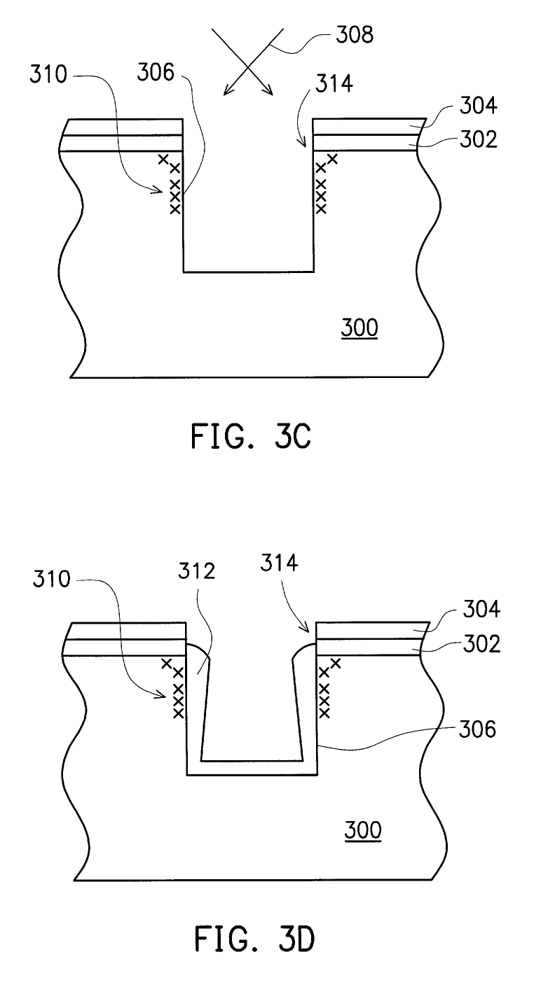

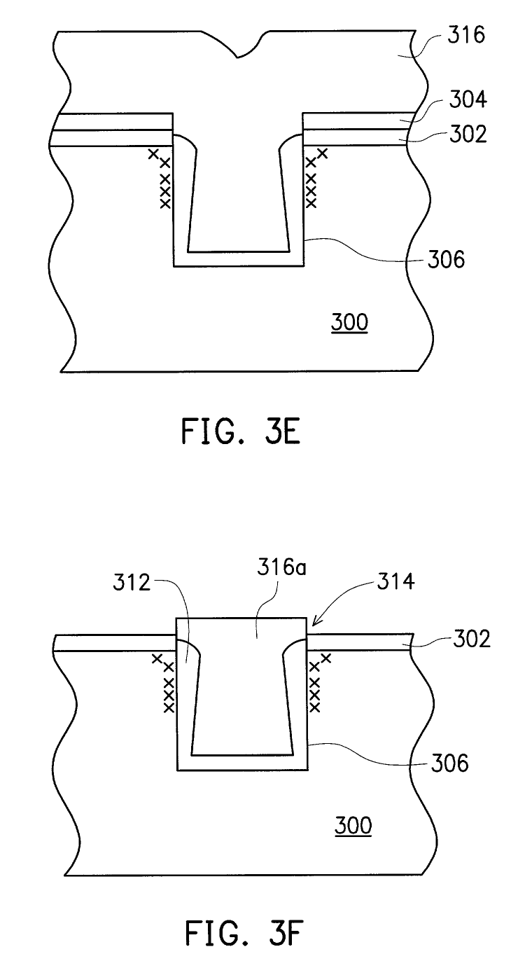

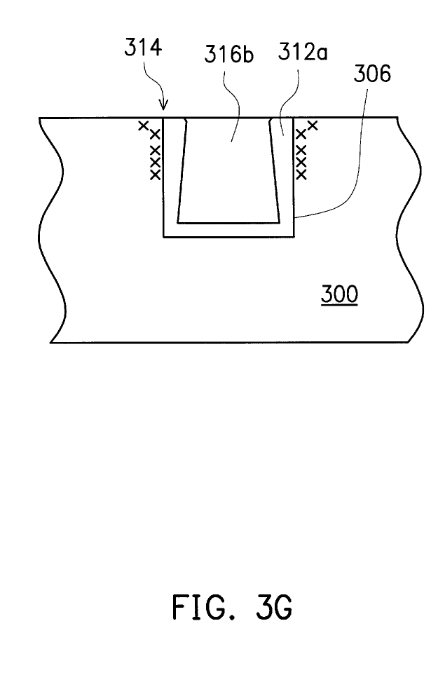

FIGS. 3A through 3G are schematic, cross-sectional views, illustrating the successive fabrication steps of a shallow trench isolation structure according to one preferred embodiment of this invention.

Referring to FIG. 3A, a pad oxide layer 302 is formed on a substrate 300. The pad oxide layer 302 is used to protect the substrate 300 from being damaged from the subsequent manufacturing process. The pad oxide layer 302 is formed by, for example, thermal oxidation. After this, a patterned mask layer 304, for example, a silicon nitride layer, is formed on the pad oxide layer 302.

As shown in FIG. 3B, the pad oxide layer 302 is etched, for example, by anisotropic etching, to the substrate 300 to form a trench 306 in the substrate 300, using the patterned mask layer 304 as a mask.

Continuing to FIG. 3C, a tilt-angled fluorine ion implantation 308 is conducted to implant fluorine ions 310 to the substrate 300 around the top corner 314 of the trench 306. The area around the top corner 314 of the trench 306, where fluorine ions are implanted, oxidizes faster than other area without the implantation of fluorine ions. A thicker oxide layer is thus formed at the area where fluorine ions are implanted than at the area where fluorine ions are absent. Furthermore, the angle, the energy and the dosage of implantation for the tilt-angled fluorine ion implantation 308 can be adjusted according to the desired thickness and location of the oxide layer.

As shown in FIG. 3D, thermal oxidation is conducted to oxidize the surface of the trench 306, forming a liner oxide layer 312 on the surface of the trench 306. Since the substrate 300 around the top corner 314 of the trench 306 comprises fluorine ions, the rate of oxidation increases to form a liner oxide layer 312 with a greater thickness than at other area. The liner oxide layer 312 around the top corner 314 of the trench 306 is actually thick enough to cover a part of the pad oxide layer 302 to protect the top corner 314 of the shallow trench isolation structure 306.

Thereafter, as shown in FIG. 3E, an insulation layer 316 is formed on the substrate 300, covering and filling the trench 306. The insulation layer 316, such as silicon oxide, is formed by, for example, high density plasma chemical vapor deposition (HDP-CVD).

Continuing to FIG. 3F, the insulation layer 316 above the mask layer 304 is removed to form the insulation layer 316a. The insulation layer 316 is removed by, for example, chemical mechanical polishing. The mask layer 304 is then removed. The mask layer 304, for example, a silicon nitride layer, is removed by hot phosphoric acid solution.

Referring to FIG. 3G, the pad oxide layer 302 is subsequently removed, for example by cleaning with hydrofluoric acid (HF). During the removal of the pad oxide layer 302, a portion of the insulation layer 316a is concurrently removed to form the shallow trench isolation structure 316b. The liner layer 312 at the top corner 314 of the trench 306 is also removed to form the liner layer 312a.

Since the liner oxide layer 312a at the top corner 314 of the trench 306 is thicker than the liner oxide layer 312a at other area, the top corner 314 of the trench 306 is thus protected. The top corner 314 of the shallow trench isolation structure 316a is prevented from forming a recess due to anisotropic etching. The exposure of the substrate 300 is also prevented. Additionally, the liner oxide layer 312a at the top corner 314 of the trench 306 protects the shallow trench isolation structure 316b by preventing the area around the top corner 314 of the trench 306 being etched. Forming a recess during the etching of the oxide layer in the subsequent semiconductor manufacturing process is thereby prevented.

According to the present invention, a tilt-angled fluorine implantation is conducted to provide the substrate around the top corner of the trench with fluorine ions. When the thermal process is conducted to form the liner layer on the surface of the trench, the trench surface with the fluorine ions oxidizes at a faster rate, a thicker liner layer is thus formed around the top corner of the trench than at other area. As a result, during the removal of the pad oxide layer and the subsequent etching of the oxide layers as in the conventional practice, the formation of a recess at the top corner of the trench isolation structure leading to the exposure of the substrate is prevented. The problem of current leakage of the device is thus mitigated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method for a shallow trench isolation structure, comprising:
providing a substrate;
forming sequentially a pad oxide layer and a patterned mask layer on the substrate;
etching the pad oxide layer and a part of the substrate to form a trench in the substrate using the patterned mask layer as a mask;
performing a tilt-angled fluorine ion implantation to implant fluorine ions to the substrate surface around a top corner of the trench;
conducting a thermal oxidation process to form a liner oxide layer on a surface of the trench, wherein the liner oxide layer at the top corner of the trench is thicker than at other area;
forming an insulation layer on the mask layer to cover and to fill the trench;
removing the insulation layer above the mask layer;
removing the mask layer; and
removing the pad oxide layer.

2. The method of claim 1, wherein the insulation layer is formed by high-density plasma chemical vapor deposition.

3. The method of claim 1, wherein the insulation layer includes silicon oxide.

4. The method of claim 1, wherein the pad oxide layer is removed by using a hydrofluoric acid (HF) solution.

5. The method of claim 1, wherein removing the insulation layer above the mask layer includes performing chemical-mechanical polishing.

6. A fabrication method for a shallow trench isolation structure, comprising:
forming sequentially a pad oxide layer and a patterned mask layer on the substrate;
etching the pad oxide layer and a part of the substrate to form a trench in the substrate using the patterned mask layer as a mask;
implanting a material to the substrate surface around a top corner of the trench, wherein the material comprises a characteristic of enhancing an oxidation rate;
forming a liner oxide layer on a surface of the trench by thermal oxidation;
forming an insulation layer on the mask layer, wherein the insulation layer fills the trench;
removing the insulation above the mask layer;
removing the mask layer; and
removing the pad oxide layer.

7. The method of claim 6, wherein the material includes fluorine ions.

8. The method of claim 6, wherein forming the insulation layer includes performing high-density plasma chemical vapor deposition.

9. The method of claim 6, wherein the insulation layer silicon oxide.

10. The method of claim 6, wherein the pad oxide layer is removed using a HF solution.

11. The method of claim 6, wherein the insulation layer above the mask layer is removed by chemical-mechanical polishing.

12. A fabrication method for a shallow trench isolation structure, comprising:
providing a substrate;
forming sequentially a pad oxide layer and a mask layer on the substrate, wherein a trench is formed in the substrate through the pad oxide layer;
forming a material in the substrate surface around a top corner of the trench, wherein the material comprises a characteristic of enhancing an oxidation rate;
performing a thermal oxidation process to form a liner oxide layer on a surface of the trench;
forming an insulation layer on the mask layer, wherein the insulation layer fills the trench;
removing the insulation layer above the mask layer;
removing the mask layer; and
removing the pad oxide layer.

13. The method of claim 12, wherein forming the material in the substrate surface around the top corner of the trench includes performing a tilt-angled ions implantation.

14. The method of claim 12, wherein the material includes fluorine ions.

15. The method of claim 12, wherein the insulation layer is formed by high density plasma chemical vapor deposition.

16. The method of claim 12, wherein the insulation layer includes silicon oxide.

17. The method of claim 12, wherein the pad oxide layer is removed by using a HF solution.

18. The method of claim 12, wherein the insulation layer above the mask layer is removed by chemical mechanical polishing.
